(19) United States
(12) Patent Application Publication
(10) Pub. No.: US 2015/0204585 A1
(43) Pub. Date: Jul. 23, 2015

(54) THERMOELECTRIC MODULE AND HEAT CONVERSION DEVICE INCLUDING THE SAME

(71) Applicant: LG INNOTEK CO., LTD., Seoul (KR)

(72) Inventors: Boone WON, Seoul (KR); Sang Gon KIM, Seoul (KR)

(21) Appl. No.: 14/602,389

(22) Filed: Jan. 22, 2015

(30) Foreign Application Priority Data
Jan. 23, 2014 (KR) 10-2014-0008429

(51) Int. Cl. F25B 21/02; H01L 35/30

(52) U.S. Cl. CPC F25B 21/02; H01L 35/30

(57) ABSTRACT

Provided is a thermoelectric module, including: a first substrate and a second substrate disposed to face each other; at least one unit thermoelectric element composed of a pair of semiconductor elements including a P-type semiconductor element and an N-type semiconductor element disposed in an internal area between the first substrate and the second substrate disposed to face each other and having respective ends electrically connected to each other via electrodes; and at least two kinds of sealing parts having different thermal conductivities and coated on at least one area of the internal area between the first substrate and the second substrate disposed to face each other.

### CROSS-REFERENCE TO RELATED APPLICATION

This application claims priority under 35 U.S.C. §119 to Korean Application No. 10-2014-008429 filed on Jan. 23, 2014, whose entire disclosure is incorporated herein by reference.

### BACKGROUND

1. Field

Embodiments of the present application relate to a thermoelectric module used for a cooling purpose.

2. Background

Generally, a thermoelectric element including thermoelectric converting elements is configured such that a P-type thermoelectric material and an N-type thermoelectric material are bonded between metal electrodes to form a PN bonding pair.

When a temperature difference is applied to the PN bonding pair, electric power is produced by a Seeback effect so that the thermoelectric element can serve as a power generation device. Furthermore, the thermoelectric element may be used as a temperature control device by a Peltier effect that one part of the PN boding pair is cooled and the other part thereof is heated.

Here, the Peltier effect refers to a phenomenon in which a p-type material hole and an N-type material electron are moved when an external DC voltage is applied thereto, thereby causing heat or heat absorption from both ends of the material. The Seeback effect refers to a phenomenon in which the hole and the electron are moved when heat is supplied from an external heat source so that current can flow through the material, thereby causing electric power.

Active cooling using such a thermoelectric material has been recognized as a friendly environment method because the active cooling can improve thermal stability of the thermoelectric element, does not cause noise and vibration, and does not use a separate condenser and refrigerant, thereby accommodating a small amount of space. The application fields for the active cooling using the thermoelectric material refer to a non-refrigerant refrigerator, an air conditioner, various micro-cooling systems, or the like. In particular, when the thermoelectric element is attached to various memory elements, the thermoelectric element can be maintained in a uniform and stable temperature with a reduction in a volume compared to that using the existing cooling method, thereby enabling the improvement of performance of the thermoelectric element.

Sealing for a unit module composed of an N-type semiconductor element and a P-type semiconductor element is performed with insulating resin upon manufacturing a thermoelectric module. This is intended to realize waterproof and insulation by blocking exposure to the outside. However, when the same sealing material is used in the module, heat build-up is generated inside the elements so that cooling efficiency can be reduced. Referring to FIG. 1, when one kind of the sealing material S is used in the module, heat H₂ generated from a heating part Zᵣ is emitted via a sealing portion and a thermoelectric element adjacent to a heat absorbing part Zₐ as well as via a lower substrate of the heating part Zᵣ. Also, the heat H₃ generated from the heating part Zᵣ is directly transmitted to the heat absorbing part Zₐ, or heat H₄ of the outside is transmitted to the heat absorbing part, thereby causing the reduction of cooling performance.

### BRIEF DESCRIPTION OF THE DRAWINGS

The embodiments will be described in detail with reference to the following drawings in which like reference numerals refer to like elements wherein:

FIG. 1 is a mimetic diagram showing heat transfer of a conventional thermoelectric module;

FIG. 2 is an exemplary cross-sectional view of a thermoelectric module according to an embodiment of the present application;

FIG. 3 is an exemplary perspective view of the thermoelectric module according to the embodiment of the present application; and

FIG. 4 is a mimetic diagram showing heat transfer of the thermoelectric module according to the embodiment of the present application.

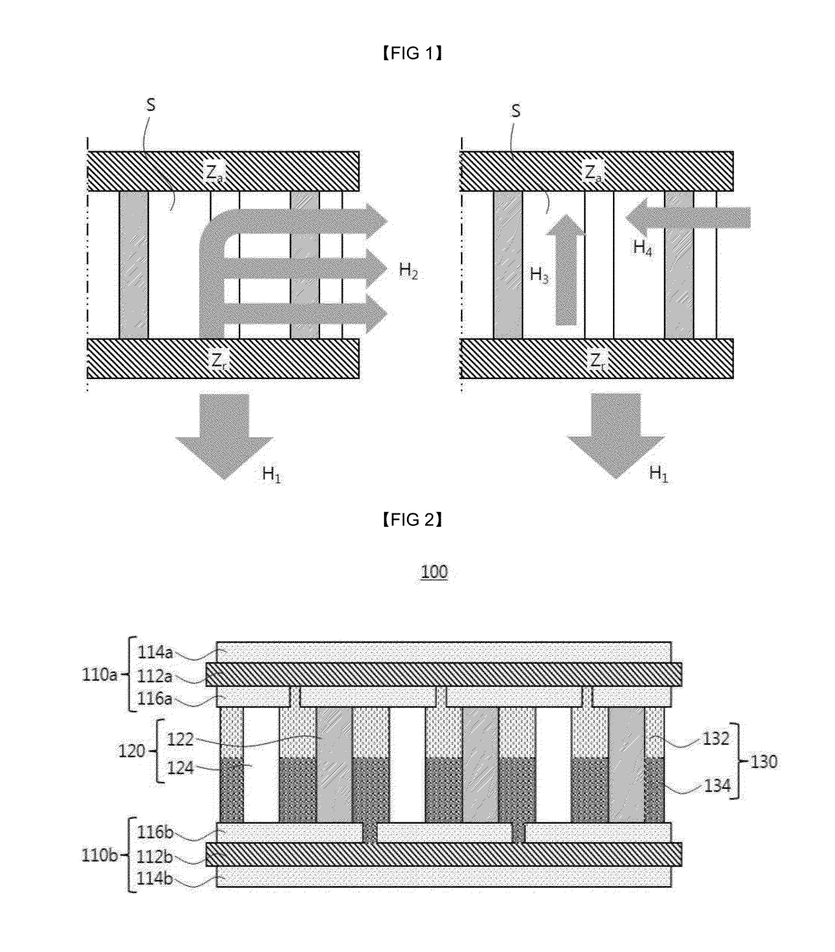

### DETAILED DESCRIPTION

Hereinafter, the configurations and operations according to embodiments of the present application will be described in detail with reference to the accompanying drawings. The present application may, however, be embodied in different forms and should not be construed as limited to the embodiments set forth herein. In the explanation with reference to the accompanying drawings, regardless of reference numerals of the drawings, like numbers refer to like elements through the specification, and repeated explanation thereon is omitted. Terms such as a first term and a second term may be used for explaining various constitutive elements, but the constitutive elements should not be limited to these terms. These terms are only used for the purpose for distinguishing a constitutive element from other constitutive element. As used herein, the singular forms “a,” “an” and “the” are intended to include the plural forms as well, unless the context clearly indicates otherwise.

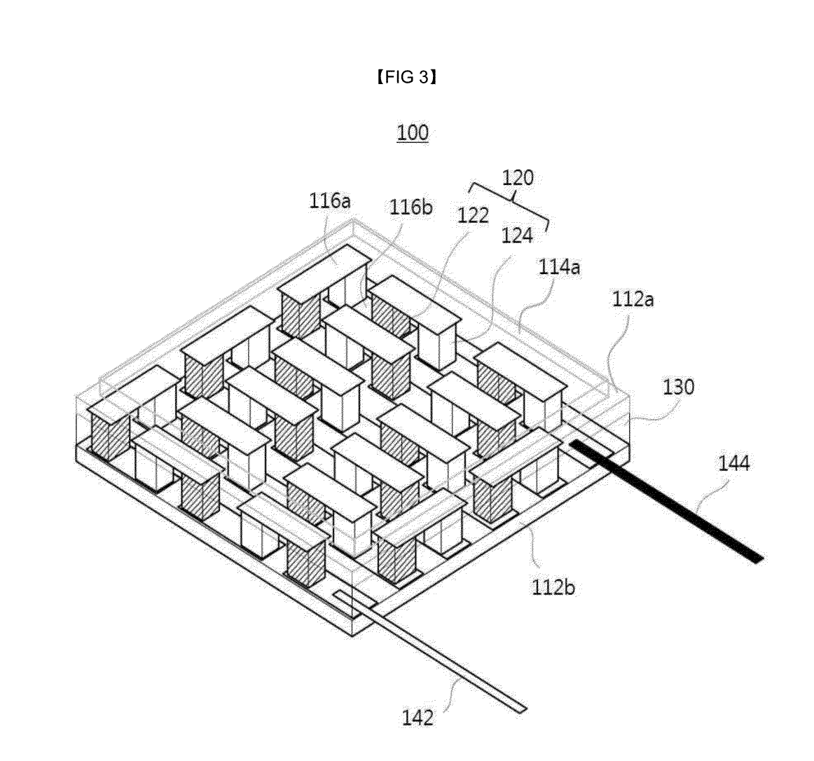

FIG. 2 is an exemplary cross-sectional view of a thermoelectric module according to an embodiment of the present application, and FIG. 3 is an exemplary perspective view of the thermoelectric module according to the embodiment of the present application.

A thermoelectric module 100 according to the present embodiment of the invention may include: a first substrate 110a and a second substrate 110b disposed to face each other; at least one unit thermoelectric element composed of a pair of semiconductor elements 120; and at least two kinds of sealing parts 130 having different thermal conductivities and coated on at least one area of the thermoelectric module.

In particular, the sealing part 130 may be partially or entirely filled in an internal area between the first substrate 110a and the second substrate 110b disposed to face each other. The sealing part 130 is intended for waterproof and insulation by blocking exposure to the outside. The sealing part 130 may be composed of an insulator. Epoxy resin, silicon resin, acrylic resin, Teflon resin, mica or the like may be used as the insulator. In the thermoelectric module according to the present embodiment, any one of the first substrate 110a and the second substrate 110b serves as a heat generating area (a heating part) and another one thereof serves as a heat absorbing area (a heat absorbing part). In order to prevent heat emitted from the heating part from flowing into the heat absorbing part, a sealing part 134 in contact with the heating part and a sealing part 132 in contact with the heat absorbing part are composed of two sealing materials having different thermal conductivities. Thus, thanks to insulation from the outside, cool air may be completely concentrated in a cooling part. Further, heat generated from the heating part is locally emitted around the heating part so that heat transfer to the heat absorbing part can be minimized, thereby enabling the improvement of cooling efficiency.

To do so, in the present embodiment of the invention, the sealing part may include at least two kinds of sealing parts coated on at least one area of the internal area between the first substrate and the second substrate disposed to face each other. As one example, as illustrated in FIG. 2, the sealing part may be implemented in a double layered structure. The sealing part 130 may include: the first sealing part 132 in contact with one surface of the first substrate 110a; and the second sealing part 134 in contact with one surface of the second substrate 110b and disposed to be in contact with at least one area of the first sealing part 132.

In particular, in the structure in which the first substrate 110a serves as the heat absorbing part, and the second substrate 110b serves as the heating part, the first sealing part 132 may be made of a material having a lower thermal conductivity than that of the second sealing part 134. This is intended to prevent heat emitted from the heating part from flowing into the heat absorbing part and to enable the heat of the heating part to be easily emitted to the outside.

For a more efficient structure, in the structure illustrated in FIG. 2, the first sealing part and the second sealing part are formed to have substantially the same volume. However, in order to increase radiant heat or heat absorbing efficiency, a volume of the first sealing part and a volume of the second sealing part may be adjusted such that the first and second sealing part have different volumes.

In the case of a cooling thermoelectric module, a general insulating substrate such as an alumina substrate may be used as the first substrate 110a and the second substrate 110b. Also, as another example, the first substrate 110a and the second substrate 110b may include ceramic substrate layers 112a, 112b, respectively. In such a case, the ceramic substrate layer may be an insulating material such as Al₂O₃, AlN, Si₃N₄ or BeO, or the like. Moreover, each thickness of the ceramic substrate layers 112a, 112b may range from 0.1 to 1 mm. When each thickness of the ceramic substrate layers 112a, 112b is less than 0.1 mm, a defect and current flow may be caused because strength of the first substrate 110a and the second substrate 110b lacks. On the contrary, when each thickness thereof is more than 1 mm, a weight of the thermoelectric module is increased in terms of the properties of a ceramic material, Thus, it is not desirable for each thickness to deviate from the range.

Also, the first substrate 110a and the second substrate 110b may be DBC (Direct Bond Copper) substrates. Both surfaces of the DBC substrate are subjected to bonding treatment with copper so as to enable soldering or wiring bonding. As shown in FIG. 2, a general structure of the DBC substrate is configured such that upper metal layers 114a, 114b are bonded to respective upper surfaces of the ceramic substrate layers 112a, 112b corresponding to insulating substrates, and lower metal layers 116a, 116b are bonded to respective lower surfaces of the ceramic substrate layers 112a, 112b. Here, “the upper metal layers” refer to metal layers bonded to respective external sides of the thermoelectric module 100 based on the first substrate 110a and the second substrate 110b, and “the lower metal layers” refer to metal layers bonded to respective internal sides of the thermoelectric module 100, namely, metal layers bonded to the semiconductor elements 120.

The upper metal layers 114a, 114b are formed on respective entire surfaces or respective partial surfaces of the ceramic substrate layers using a chemical vapor deposition (CVD) method, an evaporator, a sputtering method, a directly compression method of the metal layers, or the like. Each thickness of the upper metal layers 114a, 114b may range from 50 to 500 μm.

The lower metal layers 116a, 116b may be formed on respective one surfaces and respective another surfaces of the ceramic substrate layers 112a, 112b, namely, opposing surfaces of the ceramic substrate layers 112a, 112b. Like the method of forming the upper metal layers 114a, 114b, the lower metal layers are formed on respective entire surfaces or respective partial surfaces of the ceramic substrate layers using a chemical vapor deposition (CVD) method, an evaporator, a sputtering method, a directly compression method of the metal layers, or the like. Since the lower metal layers 116a, 116b are bonded to the semiconductor elements 120 so as to be electrodes of the semiconductor elements, the lower metal layers may be appropriately patterned according to a form and arrangement of the semiconductor elements. Each thickness of the lower metal layers 116, 116b may range from 50 to 500 μm. In particular, the lower metal layers may be applied as electrodes. When the lower metal layers are implemented as electrode layers, the upper metal layers may be omitted. The upper metal layers may serve as electrode layers for electrically connecting the first semiconductor element and the second semiconductor element using an electrode material such as Cu, Ag, Ni and the like, and each thickness of the electrode layers may range from 0.01 to 0.3 mm.

Moreover, in the case of another embodiment of the present application, the first substrate or the second substrate may be composed of a metal substrate. That is, by using the metal substrate, radiant heat efficiency and a slimming structure may be implemented. Of course, when the first substrate or the second substrate is formed as the metal substrate, a dielectric layer may be formed between the electrode layers formed on the first substrate and the second substrate. In the case of the metal substrate, Cu or a Cu alloy, a Cu—Al alloy, or the like may be applied as a material of the metal substrate. A thickness of the metal substrate may range from 0.1 to 0.5 mm so that a slimming structure can be ensured. Also, the dielectric layer is made of a dielectric material having a high radiant heat ability. In consideration of a thermal conductivity of the cooling thermoelectric module, a material having a thermal conductivity of 5-10 W/K may be used as a material of the dielectric layer, and a thickness of the dielectric layer may range from 0.01 to 0.1 mm.

In the present embodiment, a semiconductor element formed in a bulk type by applying a P-type semiconductor material or an N-type semiconductor material may be applied as the semiconductor element 120. The bulk type refers to a structure formed by pulverizing an ingot corresponding to a semiconductor material and subjecting the pulverized ingot to a refining ball mill process to obtain a sintered structure and by cutting the sintered structure. Such a bulk-type structure may be formed in one integral structure. The P-type semiconductor element 122 or 124, or the N-type semiconductor element 122 or 124 may be a Bi—Te-based semiconductor element.

The N-type semiconductor element 122 or 124 may be formed using a main raw material based on Bi—Te including Se, Ni, Al, Cu, Ag, Pb, B, Ga, Te, Bi, and In, and a mixture in which 0.001 to 1.0 wt % of Bi or Te based on the total weight of the main raw material is mixed. For example, when a Bi—Se—Te material is used as a main raw material, Bi or Te may be additionally mixed in an amount of 0.001 to 1.0 wt % based on the total weight of the Bi—Se—Te material. That is, when an amount of the Bi—Se—Te material is 100 g, additionally mixed Bi or Te may be added in an amount ranging from 0.001 to 1.0 g. As described above, when the amount of a material added to the main raw material is beyond the range from 0.001 to 0.1 wt %, thermal conductivity is not reduced, and electrical conductivity is decreased, so the improvement of a ZT value may not be expected. In light of this fact, the range has a meaning.

The P-type semiconductor element 122 or 124 may be formed using a main raw material based on Bi—Te including Se, Ni, Al, Cu, Ag, Pb, B, Ga, Te, Bi, and In, and a mixture in which 0.001 to 1.0 wt % of Bi or Te based on the total weight of the main raw material is mixed. For example, when a Bi—Se—Te material is used as a main raw material, Bi or Te may be additionally mixed in an amount of 0.001 to 1.0 wt % based on the total weight of the Bi—Se—Te material. That is, when an amount of the Bi—Se—Te material is 100 g, additionally mixed Bi or Te may be added in an amount ranging from 0.001 to 1.0 g. As described above, when the amount of a material added to the main raw material is beyond the range from 0.001 to 0.1 wt %, thermal conductivity is not reduced, and electrical conductivity is decreased, so the improvement of a ZT value may not be expected. In light of this fact, the range has a meaning.

The thermoelectric module according to the present embodiment may be configured such that semiconductor elements 130 having different materials and properties may be arranged to make a pair, and the respective semiconductor elements 120 in pairs may be configured such that a plurality of unit thermoelectric elements electrically connected by the metal electrode is arranged. In particular, in such a case, with regard to the thermoelectric elements constituting the unit thermoelectric elements, each one side thereof may be composed of the P-type semiconductor element 122 or 124 and each another side thereof may be composed of the N-type semiconductor element 122 or 124. The P-type semiconductor element 122 or 124 and the N-type semiconductor element 122 or 124 are connected to the lower metal layers 116a, 116b, respectively. Such a structure is formed in plural numbers, and a Peltier effect is implemented by circuit lines 142, 144 for supplying a current to the semiconductor elements via electrodes.

Hereinafter, a modified embodiment of another configuration applied to the thermoelectric module having the sealing part according to the embodiment of the present application of FIGS. 2 and 3 will be described.

In the present embodiment of the invention, the second substrate 110b is formed to have an area in a 1.2 to 5 folds increase compared to an area of the first substrate 110a so that the first substrate and the second substrate can be formed to have different volumes. That is, a width of the first substrate 110a is formed narrower than that of the second substrate 110b. In such a case, the substrates having the same thickness are formed to have different areas so that the respective volumes can be changed. When the area of the second substrate 110b is formed to be less than a 1.2 folds increase compared to that of the first substrate 110a, there is no large difference with existing heat conduction efficiency, and accordingly, a slimming structure becomes meaningless. Meanwhile, when the area of the second substrate 110b is formed to be more than a 5 folds increase compared to that of the first substrate 110a, it is difficult to maintain a form (for example, an opposing structure) of thermoelectric module, and heat transfer efficiency is remarkably reduced.

Moreover, in the case of the second substrate 110b, radiant heat patterns such as uneven patterns are formed on a surface of the second substrate so that a radiant heat property of the second substrate can be maximized. Thanks to such a configuration, even though the element of an existing heat sink is not used, the radiant heat property may be effectively ensured. In this case, the radiant heat patterns may be formed on one side or both sides of the surface of the second substrate. In particular, when the radiant heat patterns are formed on a surface that comes into contact with the first and second semiconductor elements, a radiant heat property and a bonding property between the thermoelectric element and the substrate can be increased.

Also, a thickness of the first substrate 110a is formed thinner than that of the second substrate 110b so that the inflow of heat into a cooling part can be easily performed and a heat transfer coefficient can be increased.

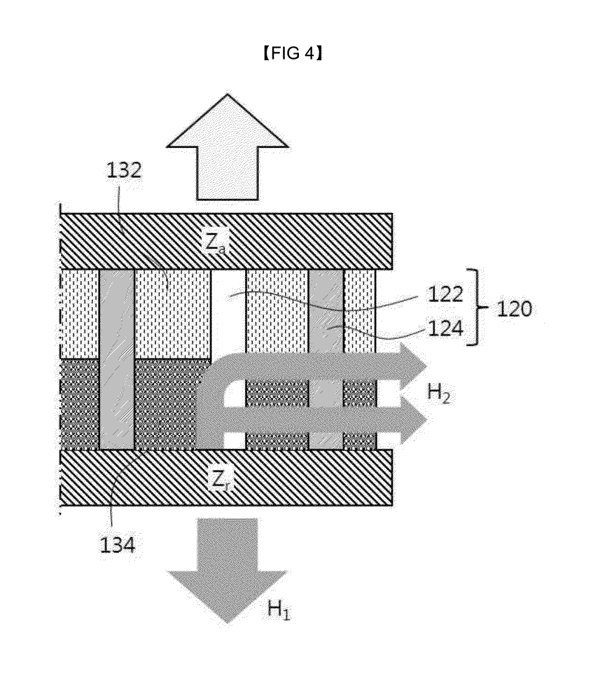

FIG. 4 is a mimetic diagram showing heat transfer of the thermoelectric module according to the embodiment of the present application.

Referring to FIG. 4, the sealing parts 132, 134 are different kinds of insulators having different thermal conductivities that are filled in a top half area and a bottom half area of the unit thermoelectric elements. In order to prevent the heat H₂ emitted from the heating part Zᵣ from flowing into the heat absorbing part Zₐ, the sealing part 134 in contact with the heating part Zᵣ and the sealing part 132 in contact with the heat absorbing part Zₐ may be formed using two different kinds of sealing materials having different thermal conductivities.

At this time, a sealing material having a high thermal conductivity is used in the heating part Zᵣ so that emission of the heat H₁, H₂ can be mostly introduced to the heating part Zᵣ. On the contrary, a sealing material having a low thermal conductivity is used in the heat absorbing part Zₐ so that the heat from the outside of the thermoelectric element to a cooling portion and the heat emitted from the heating part Zᵣ can block the heat flowing into the heat absorbing part Zₐ. The thermal conductivity may be changed according to the kind, viscosity, density or the like of the insulators. At least two insulators may be used in a state of being mixed.

A cooling device according to another aspect of the present embodiment includes a thermoelectric module, including: a first substrate and a second substrate disposed to face each other; at least one unit thermoelectric element composed of a pair of semiconductor elements disposed in an internal area between the first substrate and the second substrate disposed to face each other, the semiconductor elements having respective ends electrically connected to each other via electrodes and including a P-type semiconductor element and an N-type semiconductor element; and at least two kinds of sealing parts having different thermal conductivities and coated on at least one area of the internal area between the first substrate and the second substrate disposed to face each other.

The thermoelectric elements various structures according to the embodiment of the present application and the thermoelectric module including the thermoelectric elements may enable cooling of the surfaces of the upper and lower substrates by reducing the heat of a medium such as water or a liquid according to the properties of the heating part and the heat absorbing part, or may be used for a heating purpose by transmitting heat to a specific medium. That is, with regard to the thermoelectric module according to various embodiments of the present application, the configuration of a cooling device implemented by increasing cooling efficiency has been explained as an embodiment. However, in the substrate of an opposing surface in which cooling is performed, the thermoelectric module may be applied as a device used for heating a medium using a radiant heat property. That is, the thermoelectric module may be applied as a device that enables cooling and heating to be simultaneously implemented in one device.

As set forth above, according to some embodiments of the present application, the sealing parts arranged between the substrates facing each other are implemented in layers made of different materials having different thermal conductivities so that cool air can be completely concentrated in the cooling part thanks to insulation from the outside. Furthermore, heat generated from the heating part is locally emitted around the heating part so that heat transfer to the heat absorbing part can be minimized, thereby enabling the improvement of cooling efficiency.

The present application has been made keeping in mind the above problems, an aspect of embodiments of the present application provides a thermoelectric module, including: a first substrate and a second substrate disposed to face each other; at least one unit thermoelectric element composed of a pair of semiconductor elements disposed in an internal area between the first substrate and the second substrate disposed to face each other, the semiconductor elements having respective ends electrically connected to each other via electrodes and including a P-type semiconductor element and an N-type semiconductor element; and at least two kinds of sealing parts having different thermal conductivities and coated on at least one area of the internal area between the first substrate and the second substrate disposed to face each other.

According to an aspect of embodiments of the present application, there is provided a thermoelectric module, including: including: a first substrate and a second substrate disposed to face each other; at least one unit thermoelectric element composed of a pair of semiconductor elements disposed in an internal area between the first substrate and the second substrate disposed to face each other, the semiconductor elements having respective ends electrically connected to each other via electrodes and including a P-type semiconductor element and an N-type semiconductor element; and at least two kinds of sealing parts having different thermal conductivities and coated on at least one area of the internal area between the first substrate and the second substrate disposed to face each other.

Also, according to another aspect of embodiments of the present application, there is provided a cooling device including the thermoelectric module.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thermoelectric module, comprising:
a first substrate and a second substrate disposed to face each other;
a unit thermoelectric element disposed in an internal area between the first substrate and the second substrate disposed to face each other and including a pair of semiconductor elements electrically connected to each other; and
at least two kinds of sealing parts having different thermal conductivities and disposed in the internal area.

2. The thermoelectric module of claim 1, wherein the sealing part comprises: a first sealing part in contact with one surface of the first substrate; and a second sealing part in contact with one surface of the second substrate and disposed to come into contact with at least one area of the first sealing part.

3. The thermoelectric module of claim 2, wherein the first sealing part is composed of a material having a lower thermal conductivity than that of the second sealing part.

4. The thermoelectric module of claim 3, wherein a volume of the first sealing part and a volume of the second sealing part are substantially identical to each other.

5. The thermoelectric module of claim 3, wherein the first substrate is a heat absorbing area.

6. The thermoelectric module of claim 5, wherein the second substrate is a heating generating area, and a volume of the second sealing part is larger than that of the first sealing part.

7. The thermoelectric module of claim 6, wherein an area of the second substrate is wider than that of the first substrate.

8. The thermoelectric module of claim 5, wherein the semiconductor element comprises a first semiconductor element and a second semiconductor element electrically connected to each other.

9. The thermoelectric module of claim 8, wherein the first semiconductor element is a P-type semiconductor element, and the second semiconductor element is an N-type semiconductor element.

10. A thermoelectric module, comprising:
a first substrate and a second substrate disposed to face each other;
a unit thermoelectric element disposed in an internal area between the first substrate and the second substrate disposed to face each other and including a first semiconductor element and a second semiconductor element electrically connected to each other; and
at least two sealing parts having different conductivities and disposed in the internal area;
wherein a volume of the second semiconductor element is larger than that of the first semiconductor element.

11. The thermoelectric module of claim 10, wherein a volume of the first substrate and a volume of the second substrate are different from each other.

12. The thermoelectric module of claim 10, further comprising electrode layers on the first substrate and the second substrate.

13. The thermoelectric module of claim 12, wherein the first substrate and the second substrate are metal substrates.

14. The thermoelectric module of claim 13, wherein a thickness of the first substrate is thinner than that of the second substrate.

15. The thermoelectric module of claim 13, further a dielectric layer between the first substrate and the second substrate.

16. The thermoelectric module of claim 10, wherein the first substrate and the second substrate are DBC (Direct Bond Copper) substrates in which respective ceramic substrate layers are interposed between respective upper metal layers and respective lower metal layers.

17. The thermoelectric module of claim 10, wherein the first semiconductor element and the second semiconductor element are composed of a mixture in which Bi or Te is mixed with a BiTe-based main raw material.

18. The thermoelectric module of claim 10, wherein a ratio of an area of the first substrate to an area of the second substrate is in the range of 1:1.2 to 5.

19. The thermoelectric module of claim 10, further radiant patterns on any one surface of the first substrate and the second substrate.

20. A heat conversion device including a thermoelectric module according to claim 3.
